(19) United States
(12) Patent Application Publication
(10) Pub. No.: US 2025/0008711 A1
(43) Pub. Date: Jan. 2, 2025

(54) METHOD AND APPARATUS FOR STIFFENING AN ELECTRONIC DEVICE

(71) Applicant: Intel Corporation, Santa Clara, CA (US)

(72) Inventors: Juha PAAVOLA, Hillsboro, OR (US); Curtis KOEPSELL, Beaverton, WA (US); Sami HEINISUO, Dallas, OR (US); Kari MANSUKOSKI, Hillsboro, OR (US); Jeff KU, Taipei City (TW)

(21) Appl. No.: 18/344,934

(22) Filed: Jun. 30, 2023

(51) Int. Cl. H05K 9/00; H05K 1/02

(52) U.S. Cl. CPC H05K 9/0032; H05K 1/0203

(57) ABSTRACT

An electronic device and method for assembling an electronic device. The device includes a shielding structure at least partially, laterally surrounding an electrical component on a circuit board. The device further includes a lid affixed to the top of the shielding structure and covering the electrical component, a spring directly or indirectly applying a load force to the electronic component, and a fastener affixing the lid and the spring to the circuit board.

### BACKGROUND

As the design of electronic devices trends towards thinner and lighter products, the rigidity of the internal components is increasingly important. Thin electronic devices are more susceptible to twisting, warping, bending, and/or other external forces. When this happens, internal components, such as electronic packages, risk solder joint failure, cracks, and/or poor thermal performance due to the reduced pressure of cooling structures. Therefore, an improved method and apparatus for stiffening electronic devices is desired.

### BRIEF DESCRIPTION OF THE FIGURES

Some examples of apparatuses and/or methods will be described in the following by way of example only, and with reference to the accompanying figures, in which

FIG. 1A shows a schematic cross-section of an electronic device with a stiffening lid;

FIG. 1B shows a schematic cross-section of an electronic device with a stiffening lid;

FIG. 2 shows a top-down view of an electronic device with risk areas highlighted;

FIG. 3 shows a device with a stiffening lid over an electronic component;

FIG. 4 shows a flowchart of a method for assembling an electronic device with a stiffening lid; and

FIGS. 5A and 5B show simulations of a circuit board without and with a stiffening lid.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

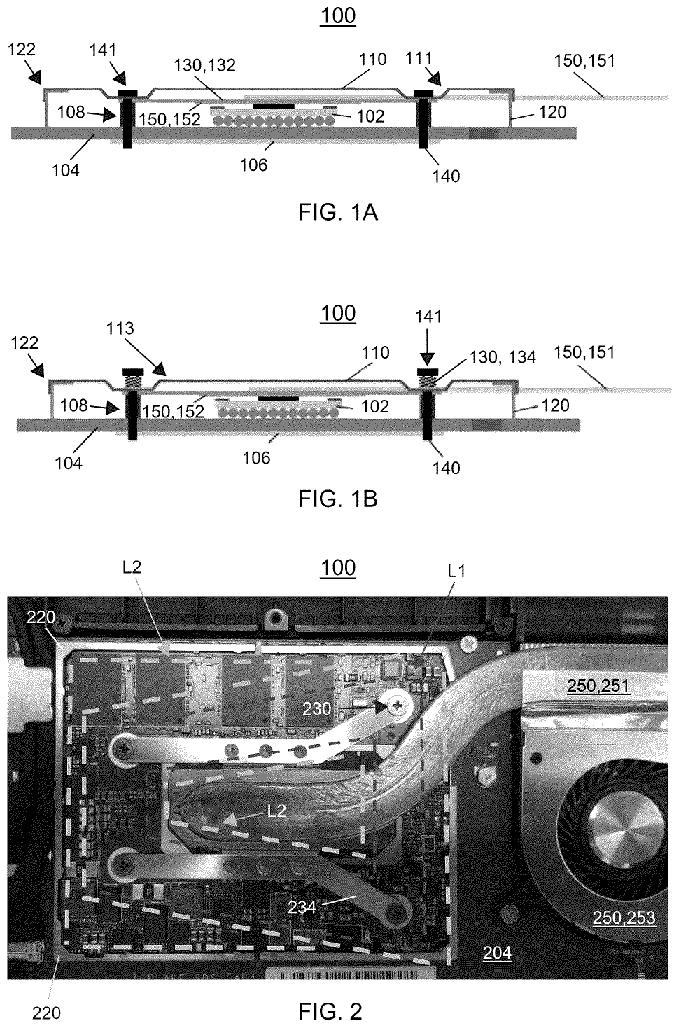

FIGS. 1A and 1B show schematic cross-sections of electronic devices 100 with a stiffening lid 110. The electronic devices 100 include a shielding structure 120 at least partially, laterally surrounding an electrical component 102 on a circuit board 104. The devices further include a lid 110 affixed to the top of the shielding structure 120 and covering the electrical component 102, a spring 130 directly and/or indirectly applying a load force to the electrical component 102, and a fastener 140 affixing the lid 110 and the spring 130 to the circuit board 104.

FIG. 2 shows a top-down view of an electronic device 100 (e.g. of FIG. 1A). Specifically, it shows a top-down view of an electronic device with risk areas highlighted. Line L1 shows where a backing plate underneath the circuit board 204 would like. The backing plate shown by L1 would be connected via fasteners 230 to the leaf springs 232. The springs then drive the heat pipe 251 cooling structure 250 (directly or indirectly) against an electronic component or component stack between the heat pipe 251 and the circuit board 204. The electrical component is surrounded by a shielding structure 220 (e.g. an EMI fence) and protected on top by a lid (not shown). The heat pipe 251 is affixed to an electronic component on one, proximal end and a fan 253 on the other, distal end. When a circuit board 204 with an electrical component or component stack is put under stress, the highest failure risk areas (shown by line L2) may be next to the edges of a shielding structure 220 or fence or next to a base plate or backing plate (under the circuit board 204, shown by line L1). This failure may be caused by twisting, warping, bending, and/or other external forces. However, when a lid is fastened the circuit board 204 via fasteners 230, the lid may carry membrane loads during bending since it is also connected to the shielding structure 220.

This lateral stiffness of a lid (e.g. an EMI lid) may be utilized to improve circuit board (e.g. PCB) stiffness at the area of an electronic component (e.g. a processor). Lateral stiffness refers to the resistance of an object or structure to deformation or displacement in the horizontal or sideways direction. It measures the ability of the object to resist bending or flexing when subjected to lateral loads or forces. In the context of electronic packages, lateral stiffness may be important for maintaining the stability and integrity of the package during operation and handling. A higher lateral stiffness ensures that the components and structures within the package remain securely positioned and aligned, reducing the risk of misalignment, damage, or malfunction. Lateral stiffness may help prevent unwanted movement or vibrations that could negatively impact the performance or reliability of the electronic device. By enhancing lateral stiffness, the overall mechanical stability and robustness of the electronic package are improved, contributing to its longevity, and/or optimal functionality.

As shown in FIGS. 1A and 1B, a shielding structure 120, such as an EMI fence or a protective fence, may provide a protective configuration designed to mitigate electromagnetic interference, particularly in the lateral direction. For example, this structure may be constructed from conductive materials and forms a barrier around a semiconductor device (e.g. a processor). It may be integral to the circuit board 104 or affixed at the bottom to the circuit board 104. At its top, it may be affixed to a lid 110, such as an EMI lid or a protective lid. The shielding structure 120 may effectively contain electromagnetic emissions generated by the internal circuitry and minimize their impact on neighboring electrical components. The shielding structure 120 acts as a shield, impeding the ingress or egress of external electromagnetic signals, thereby preserving the integrity of an enclosed processor (or other components), and promoting the optimal performance of the electronic device 100 or package as a whole.

A lid 110 encompasses a range of protective and utilitarian functionalities. The lid 110, for example, may be crafted from rigid or semi-rigid materials such as metal or other electrically conductive material, may assume a primary role in enveloping and safeguarding the delicate internal components of the device. A lid 110 may be attached with a thermal solution to underlying components. A thickness of the lid 110 may be 0.10 millimeters (or at least 0.05 mm, or at least 0.25 mm, or at least 0.15 mm, or at least 0.1) and/or at most 0.2 millimeters (or at most 0.01, or at most 0.15, or at most 0.45, or at most 1 mm). The lid 110 may provide structural integrity and act as a barrier against external impacts, dust, or moisture and/or may avoid or reduce electromagnetic interference. A lid 110 may incorporate thermal management features, including vents, which aid in the efficient dissipation of heat generated by a processor during operation. The lid 110 may extend over the electrical component 102. For example, the electrical component 102 may be arranged between the lid 110 and the circuit board 104.

For example, the lid 110 may be affixed to the shielding structure 120 using snap-fit connections, interlocking tabs or grooves, threaded fasteners, adhesive bonding, and/or any combination of these methods. Supporting the lid 110 with the shielding structure 120 allows for the lid 110 to be used as a stiffener within the component stack. Using a lid 110 as a topside stiffener may increase the circuit board 104 stiffness by 50-120% depending on the design. A diagram of the proposed solution. When the lid 100 is affixed to the circuit board 104 (e.g. attached by screws to the stack), the lid may carry membrane loads during bending since it is connected to the shielding structure 120 (e.g. fence). This may be further enhanced when the connection to the structure is rigid (e.g. affixed with stiff corners and snaps).

Using a lid 110 a stiffener may have many benefits. For example, a stiffening lid may reduce the thickness of the connecting circuit board 104 or any backing plate 106. Reducing thickness would also reduce the system height (e.g. Z-stack) and arrest any increase in weight. It may also reduce the weight of the system through enabling thinner system components, or the omission of components such as a backing plate 106. Using a lid 110 as a stiffener may also reduce the stress on solder joints such as those present in a ball grid array (BGA). Reducing BGA stresses may also improve the mechanical reliability of the electronic device 100 or package. Further, this arrangement may prevent routing layer cracks at the circuit board. A routing layer crack refers to a fracture or break that occurs within one of the routing layers of a circuit board or PCB. PCBs consist of multiple layers of conductive traces, also known as routing layers, that are interconnected to form electrical pathways for the flow of signals and power. These routing layers are typically separated by insulating material called the substrate. Additionally, fixing the lid 110 to the circuit board 104 using fasteners may have a minimal effect on the material or assembly cost of the device.

The shielding structure 120 may partially or completely, laterally surround the electrical component 102. For example, shielding structure 120 may completely encircle the electrical component 102 on the circuit board. Alternatively, the shielding structure 120 may only partially, laterally surround the electrical component 102. For example, the shielding structure 120 may encircle the electrical component 102 along at least 50% (or at least 70% or at least 90%) of a circumference of the electrical component 102. For example, the shielding structure 120 may completely encircle the electrical component 102 except for an opening for a structure (e.g. cooling structure 150) extending into a cavity enclosed by the circuit board, the shielding structure 120 and the lid 110.

The shielding structure 120 may only partially enclose a component to allow access to the internals for specific purposes, such as heat dissipation through a heat pipe 151. This is shown in FIG. 2 where the shielding structure 220 leaves space for the heat pipe 251 to extend from the electrical component to the fan 253. By leaving a portion of the component exposed, it may help more efficiently transfer thermal energy to an external cooling system. A partial enclosure may also afford accessibility for connectors, mechanical components (e.g. buttons or switches), modularity for sub-components, and/or signal transmission. For example, a shielding structure 120 may have gaps or slots to enable the transmission of specific signals, such as wireless or RF signals, while still providing partial electromagnetic shielding to protect sensitive internal circuitry.

A load force, in the context of spring screw 134 (e.g. FIG. 1B) or leaf spring 132 (e.g. FIG. 1A) application, refers to the force exerted on a processor (e.g. CPU or GPU) or another component to ensure proper mechanical contact or thermal conductivity. A load force may be generated by the compression or tension of the spring mechanism. For example, if a spring-loaded screw is tightened or a leaf spring 132 is flexed, the resulting load force may be applied to the underlying component or component stack. This ensures sufficient pressure between, for example, a processor and its heatsink or thermal interface material. This pressure may promote effective heat transfer and may help maintain the optimal thermal performance of the processor. When a lid 110 is attached to the shielding structure 120 (e.g. a shielding fence) and connected by the fastener, the lid 110 transfers a part of the load to the fence. The load may be transferred closer to the fasteners (e.g. mounting screws) and thereby may decrease the board deflection.

A spring 130 is a mechanical component (e.g. comprising metal) that is designed to store and release mechanical energy. It is characterized by its ability to deform when a force is applied and then return to its original shape when the force is removed. Springs are widely used in various applications to provide tension, compression, and/or torsion forces, enabling them to serve purposes such as shock absorption, maintaining contact pressure, storing energy, and/or facilitating mechanical movement.

A spring 130 may release its stored potential energy into kinetic energy, causing the spring 130 to push or pull directly on an object, thereby exerting a force (e.g. a load force). The force may be directly exerted on an affixed, abutting, and/or otherwise adjacent component. The force may also be indirectly exerted or applied to a series of components in direct contact or indirect contact with the spring 130. This direct and indirect application of force may aid with dampening vibrations or facilitating contact pressure between components.

The fastener 140 may be a device or component used to securely join or hold together two or more objects. It may be designed to provide mechanical strength and stability to the assembly by creating a reliable and durable connection. Fasteners come in various forms, such as screws, bolts, rivets, and/or clips. They also may be made from materials like metal, plastic, and/or composite materials. The fastener 140 may feature a threaded or grooved structure that allows them to be easily inserted, tightened, and/or secured in place. For example, fasteners play a critical role in the assembly of electronic devices, ensuring the structural integrity and reliability of the components and allowing for efficient maintenance and repair when necessary. The fastener 140 may attach the lid 110 with a thermal solution and the package so that the whole stack may work as a honeycomb structure. The lid 110 may work as a membrane part and therefore it may be very thin (e.g. 0.10 mm to 0.20 mm).

The devices of FIGS. 1A and 1B may further comprise a cooling structure 150 arranged between the lid 110 and the circuit board 104. For example, the cooling structure 150 is a component or system designed to dissipate heat from an object or an environment, thereby reducing its temperature and maintaining thermal balance. It may provide a pathway for transferring heat away from the heat source and dispersing it into the surrounding environment. The cooling structure 150 may be or may comprise a heat pipe 151, a heat exchanger, a liquid cooling system, a heat sink, a vapor chamber, and/or a cold plate 152. Arranging a cooling structure 150 between a lid 110 and a circuit board 104 may enhance heat dissipation and temperature regulation, improving the overall thermal performance and reliability of the electronic device 100.

The circuit board 104 (e.g. a printed circuit board (PCB)), may be a rigid or flexible board comprising non-conductive material (e.g. fiberglass or epoxy) with conductive pathways etched, disposed, and/or printed onto its surface. It may serve as a platform for assembling and interconnecting electrical components, enabling the flow of electrical signals and power between them to form a functional electronic system or device. A thickness of the circuit board 104 may be at least 0.5 millimeters (or at least 0.1 mm, at least 0.25 mm, at least 1 mm) and/or at most 2 mm (or at most 1 mm, at most 0.7 mm or at most 0.5 mm). Using the lid 110 as a stiffening component enables a PCB thickness of 0.50 millimeters or less.

The load force may drive the cooling structure 150 towards the top of the electrical component 102. Driving the cooling structure 150 toward the electrical component 102 may ensure effective heat dissipation while maintaining proper mechanical contact, promoting optimal thermal performance and component reliability in the electronic package.

The electrical component 102 may refer to discrete devices, integrated circuits (ICs), and/or semiconductor components that contribute to the operation and functionality of an electronic device 100 or system. For example, the electrical component 102 may be a processor (e.g. CPU, GPU, XPU, microcontroller, and/or digital signal processor), a memory or a transceiver. These components, which are often found on a circuit board 104, enable the processing, storage, and/or manipulation of electrical signals and data within an electronic device 100. Moreover, using the lid 110 as a stiffening component may decrease the mechanical failure risk of a CPU and other core area components.

The cooling structure 150 may extend from the top of the electrical component 102 through an opening in the shielding structure 120 or between the shielding structure 120 and the lid 110. Extending a cooling structure 150 through an opening in the shielding structure 120 may allow for enhanced cooling of specific components or areas within the electronic package while maintaining the necessary electromagnetic shielding for sensitive components.

For example, additional cooling structures, devices, and/or components may be arranged outside the shielding structure 120 and connected via a heat pipe 151 or similar element. This may allow the use of a larger or better-located cooling structure 150 than may be possible or desired if it were completely enclosed by the lid 110 and shielding structure 120. Connecting the cooling structure 150 through an opening in the shielding structure 120 may also allow for a reduced height or thickness of the electronic device 100 by reducing the necessary height of the components shielded by the structure and lid 110.

FIG. 2 shows an example for extending the cooling structure 250 to a fan 253. A fan may be a cooling structure 250 or an additional cooling structure as part of a cooling structure system. Extending a cooling structure to a fan external to the shielding structure may better remove heat from the electrical component within the shielding structure. Adding a fan to a cooling structure system may also enable active cooling versus passive cooling structures. It also may allow for better air circulation within the entire device, including that which passes over, around, and/or through the electronic device with the lid and shielding structure 220. Fans also may be adjustable, beneficial in enclosed or tight spaces, and effective in high heat load scenarios. This may allow for a more thermally intensive processor or other electrical components to be shielded by the lid and shielding structure 220.

The cooling structure 250 may be or may comprise a thermal interface material, a vapor chamber, a heat pipe 251, a liquid cooling system, a phase-change cooling system, and/or a cold plate. The suitability of a cooling structure 250 depends on the specific application, available space, power requirements, noise considerations, and other factors. Different cooling solutions may be more appropriate in certain situations, and the optimal choice depends on the specific cooling requirements of the electronic package.

FIG. 1B shows a spring 130 applying the load force to the lid 110 and driving the cooling structure 150 toward the top of the electrical component 102 through the lid 110. Applying a load force through a lid 110 using a spring 130 may improve mechanical stability and reduce stress on the cooling structure 150 or electrical component 102. Distributing load forces through the lid 110 may minimize direct pressure on the component, thereby enhancing its structural integrity and reducing the risk of damage or failure, while still maintaining the necessary electromagnetic shielding for optimal performance and protection.

The spring 130 may be arranged between the lid 110 and a head 141 of the fastener 140. Arranging a spring 130 between the lid 110 and the head 141 of a fastener 140, such as a spring-loaded screw 134, may provide the benefit of consistent and controlled pressure. The spring 130 may apply a constant force to maintain a secure and even contact between the lid 110 and the fastener 140. Additionally, arranging springs between the lid 110 and the head of the fastener 140 may allow for easier installation and adjustment of the springs.

Screws with springs may be commonly referred to as “spring-loaded screws” or “spring screws.” These screws feature a coiled spring that is integrated into the screw assembly, typically positioned between the head of the screw and the threaded portion. This arrangement of a spring and a screw may provide controlled tension or compression force when the screw is tightened or released.

FIG. 1A shows a spring 130 arranged between the lid 110 and the circuit board 104. Arranging a spring 130 in this manner may allow for the spring 130 to be more independent from the fastener 140. It also may allow the spring 130 to apply controlled and specific pressure toward specific components below the lid 110 (e.g. through the use of a leaf spring 132) instead of evenly applied across the lid 110. This may be useful when different components require individual load forces.

The spring 130 may extend from the fastener 140 to the top of the electrical component 102. Extending the spring 130 between a fastener 140 and the electrical component 102 may enable a secure and stable connection between the two. This arrangement may help to improve enhance mechanical stability and apply targeted and adjustable pressure to the electrical component 102.

The electronic device 100 may be a personal computer, a laptop, a tablet, a smartphone, or another device comprising an electrical component 102 to be shielded and/or cooled.

The lid 110 may include an aperture through which the fastener 140 extends. This may allow for simplified and straightforward assembly of the electronic device 100. It may also streamline the servicing or replacement of components within the electronic device.

An aperture (e.g. a screw hole) may be an opening or perforation in a surface or material of the lid 110 that may be specifically designed to accommodate the insertion and fastening of a fastener 140. It may be a specifically shaped and sized void that provides a secure and precise location for the fastener to be positioned and tightened. The aperture may be circular or cylindrical in shape, matching the form of the fastener (e.g. the threaded portion of a screw), and may be strategically placed in the lid 110 to align with corresponding holes or features in other components (e.g. a leaf spring 132, a stud 108, a circuit board 104, and/or a backing plate 106). It may allow the fastener to pass through and engage with the underlying structure and may enable the secure attachment and assembly of different parts. Apertures, may ensure proper alignment, provide stability, and facilitate the fastening of components, enhancing the overall structural integrity and functionality of the electronic device.

The aperture may be arranged in a recess 111 or protrusion 113 of the lid 110. A recess 211 may refer to a lowered or indented area or cavity intentionally created on the surface. It may be a concave or sunken portion that deviates from the surrounding flat or raised surface of the lid 110. The recess 111 of the lid 110 may have a depth equal to or greater than the height of the head 141 of the fastener 140. Having a recess 111 in the lid 110 with a depth equal to or greater than the height of the head 141 of the fastener 140 may offer of flush or recessed fastener 140 integration. This ensures that the fastener 140 head is fully contained within the recess 111, providing a level or lowered surface. This may offer improved aesthetics, reduced risk of snagging or accidental contact, and/or enhanced protection against potential damage or dislodgment of the fastener 140 head 141.

A protrusion may refer to a raised or extended portion that extends outward from a surface of the lid 110, creating a projection or prominence. The protrusion 113 may afford space underneath the lid 110 for raised components (e.g. a heat pipe 151 or a component stack with an electrical component 102). Recesses or protrusions of a lid 110 may better conform the lid 110 to the components that it protects.

A seal may be arranged between the fastener 140 and an aperture. Adding a seal between a fastener 140 and an aperture may act as a barrier, preventing the ingress of dust, moisture, and/or other contaminants into the enclosure. Additionally, the seal may help maintain the integrity of the EMI shielding by sealing any potential gaps or openings around the fastener 140, thereby reducing the risk of electromagnetic interference leakage or penetration. This may ensure improved performance, reliability, and/or longevity of the electrical components within the enclosure.

FIGS. 1A and 1B further show that the lid 110 may be affixed to the shielding structure 120 via a snap connection 122. Snap connections between the lid 110 and the fence may be very strong and allow for easy attachment. The snapping mechanism ensures a firm and reliable attachment as well as provides consistent and uniform pressure distribution across the contact area, ensuring reliable electromagnetic shielding. The strength of the attachment may be so great that the lid 110 is not possible to detach or remove without failures or possibly destroying it. This means that the connection of the lid 110 and the fence via a snap connection 122 may have an excellent capability to carry membrane loads. Moreover, when the lid 110 is screwed by screws to the stack, the lid 110 may carry membrane loads during bending since it is connected to the shielding structure 120 by stiff corners and the snap connection.

The fastener 140 may be a screw, a bolt, and/or a rivet. Screws may offer adjustable tension, easy installation and removal, and/or compatibility with a wide range of materials, making them versatile and convenient fasteners in electronic devices. Screws may also be more consistent with applying a load force. Bolts may provide high strength and load-bearing capacity, ensuring robust and secure connections in electronic devices subjected to heavy loads or vibrations. Rivets may offer permanent and tamper-resistant fastening. They may be ideal for applications where disassembly or removal is not required, providing enhanced security and reliability in electronic devices.

The spring 130 may be a leaf spring 132. The use of a leaf spring 132 may provide flexible shock absorption, uniform pressure distribution, adjustable force, space efficiency, and/or long-term reliability. The leaf spring 132 may be affixed by a second or further fastener to the circuit board 104. Affixing a leaf spring 132 to a circuit board 104 with two or more fasteners offers the benefit of secure and evenly distributed pressure, ensuring reliable electrical connections and minimizing the risk of intermittent contacts or signal disruptions within the electronic device 100.

The shielding structure 120 and the lid 110 may be grounded. Grounding the lid 110 and shielding structure 120 may provide effective electromagnetic shielding by creating a low impedance path for the dissipation of electromagnetic interference, thus reducing the risk of EMI-related issues and ensuring the proper functioning of sensitive electrical components within the device.

The circuit board 104 may comprise a stud 108 and wherein the fastener 140 is affixed to the stud 108 of the circuit board 104. A stud 108 may refer to a cylindrical or threaded rod-like component that may be protruding from a surface or embedded within the circuit board 104. It may serve as a rigid and secure point of attachment for other components, allowing for the connection of various parts or structures in a mechanical assembly. Studs 108 may comprise metal or other sturdy materials and are often used in combination with nuts, washers, and/or threaded connections to provide a reliable and adjustable fastening solution.

A connection to the stud 108 may allow for enhanced mechanical stability and strength to the fastening connection, particularly in applications where the electronic device 100 may be subjected to vibrations, shocks, and/or external forces. Additionally, the inclusion of a stud 108 in the circuit board 104 may reduce the necessity of a separate backing plate 106. This may simplify assembly and potentially save space, resulting in a more efficient and cost-effective design for the electronic device 100.

A spacer may be arranged between the lid 110 and the circuit board 104 and wherein the fastener 140 extends through the spacer. The addition of a spacer between the lid 110 and the components of the stack may provide a controlled and consistent separation distance. This may ensure proper alignment, prevent contact or interference between the components, and/or maintain desired thermal, electrical, and/or mechanical properties within the stack, enhancing the overall performance and reliability of the electronic device 100.

The circuit board 104 may be arranged between the lid 110 and a backing plate 106. The lid 110 may then be affixed to the circuit board 104 and the backing plate 106 by the fastener 140. A baseplate or backing plate 106 may add rigidity to the package, thereby protecting internal components from mechanical stresses and minimizing the risk of damage. It may also dampen vibrations, dissipate heat, and/or may contribute to electromagnetic interference (EMI) shielding.

The electrical component 102 may be a processor, a memory device, an integrated circuit, a transistor, and/or a power supply unit. Electrical components commonly found on a circuit board 104 may encompass a wide range of devices. These components are crucial for the operation of electronic devices, performing functions such as data processing, storage, signal amplification, and/or power regulation. Moreover, more than one electrical component 102 may be shielded by a single lid 110 and shielding component (e.g. a fence) on a circuit board 104.

The lid 110 may be an electromagnetic interference lid 110. EMI lids may comprise an electrically conductive material and are designed to minimize electromagnetic emissions and attenuate external electromagnetic interference. The lid 110 may enclose and shield the processor, thereby preventing electromagnetic waves generated by the internal circuitry from escaping and interfering with neighboring electrical components. An EMI lid 110 may also enclose other electrical components such as memory modules, graphics cards, and/or communication modules within an electronic package.

Moreover, the EMI lid 110 acts as a barrier, preventing external electromagnetic signals from infiltrating and adversely affecting the sensitive operation of the enclosed processor. This contributes to overall system reliability and performance. The lid 110 incorporates features such as electrically conductive gaskets or seals to ensure a robust electromagnetic seal between the lid 110 and the surrounding package structure. The EMI lid 110 further includes appropriate grounding provisions, establishing an electrical connection to the package or system ground, thereby dissipating any residual electromagnetic energy. This EMI lid 110, with its distinct configuration and materials, represents an effective means of controlling electromagnetic emissions and enhancing electromagnetic compatibility within the electronic package, thereby contributing to overall system reliability and performance.

The shielding structure 120 may be an electromagnetic interference fence. EMI fences may provide effective protection against electromagnetic interference within an electronic package. By surrounding sensitive components or areas, the EMI fence prevents unwanted electromagnetic signals from entering or exiting the enclosure, ensuring proper functioning and minimizing interference with other nearby electronic devices. This shielding structure 120 may act as a barrier, reducing the risk of electromagnetic noise and maintaining the integrity of signals and data within the electronic package.

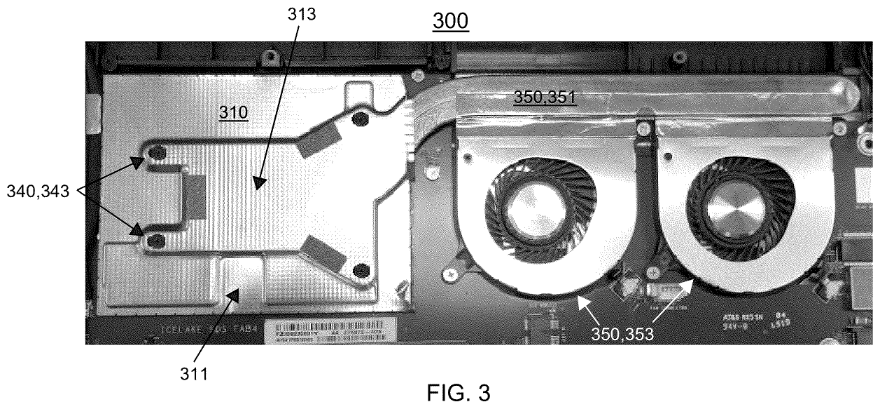

More details and aspects are mentioned in connection with the embodiments described above or below. The examples shown in FIGS. 1A, 1B, and/or 2 may comprise one or more optional additional features corresponding to one or more aspects mentioned in connection with the proposed concept or one or more examples described below (e.g. FIG. 3-5B).

FIG. 3 shows a device with a stiffening lid 310 over an electronic component with cooling structures 350 in the form of a heat pipe 351 extending to two fans 353. The figure shows that the lid 310 may include an aperture 343 through which the fastener 340 extends. This may allow for simplified and straightforward assembly of the electronic device 300. It may also streamline the servicing or replacement of components within the electronic device.

The aperture 343 may be arranged in a protrusion 313 of the lid 310. The protrusion may afford space underneath the lid 310 for raised components (such as the heat pipe 351 cooling structure 350) while allowing the remainder of the lid 310 to remain closer to the circuit board 304. It also may provide a raised area around the aperture 343, making it more visible and easier to locate during assembly or disassembly.

The lid 310 may have a recess 311. A recess 311 may refer to a lowered or indented area or cavity intentionally created on the surface. It may be a concave or sunken portion that deviates from the surrounding flat or raised surface. The purpose of a recess 311 may vary, including providing space for component placement, accommodating fasteners, and/or enhancing the overall design or functionality of the structure. Where the load force is applied to the lid 310, a recess 311 with a fastener 340 may also allow for better or more targeted application of force to the underlying components or circuit board 304 by extending the lid 310 downward in areas where a fastener 340 connects to the circuit board 304 while remaining flat or otherwise arranged in areas where force is not desired to be applied.

The recess 311 of the lid 310 may have a depth equal to or greater than the height of the head of the fastener 340. Having a recess 311 in the lid 310 with a depth equal to or greater than the height of the head of the fastener 340 may offer of flush or recessed fastener 340 integration. This ensures that the fastener 340 head is fully contained within the recess 311, providing a level or lowered surface. This may offer improved aesthetics, reduced risk of snagging or accidental contact, and/or enhanced protection against potential damage or dislodgment of the fastener 340 head 341.

Recesses or protrusions of an EMI lid 310 may better conform the lid 310 to the components that it protects. An EMI lid 310 closely conforming to the shape and contours of the components it shields may create a more effective and reliable electromagnetic barrier. This close conformance minimizes gaps and spaces that could potentially allow electromagnetic interference to leak or penetrate, ensuring better shielding performance and reducing the risk of interference affecting the sensitive electrical components within the enclosure. Additionally, this close conformance may reduce the height of the system by allowing components outside the lid 310 to take up the freed space outside of the shielding.

A seal may be arranged between the fastener 340 and an aperture 343. Adding a seal between a fastener 340 and an aperture 343 may act as a barrier, preventing the ingress of dust, moisture, and/or other contaminants into the enclosure. Additionally, the seal may help maintain the integrity of the EMI shielding by sealing any potential gaps or openings around the fastener 340, thereby reducing the risk of electromagnetic interference leakage or penetration. This may ensure improved performance, reliability, and/or longevity of the electrical components within the enclosure.

The seal may be an EMI gasket or a conductive coating. An EMI gasket (e.g., a gasket comprising conductive materials) may create a reliable seal around the fastener 340 and aperture 343, effectively blocking electromagnetic waves from entering or exiting the enclosure. Similarly, a conductive coating applied to the seal may provide an additional layer of conductivity and ensure a continuous conductive path, minimizing the potential for electromagnetic interference. A combination of the two may optimize the overall shielding effectiveness, maintaining the integrity of the enclosure and protecting the enclosed electrical components from harmful electromagnetic waves.

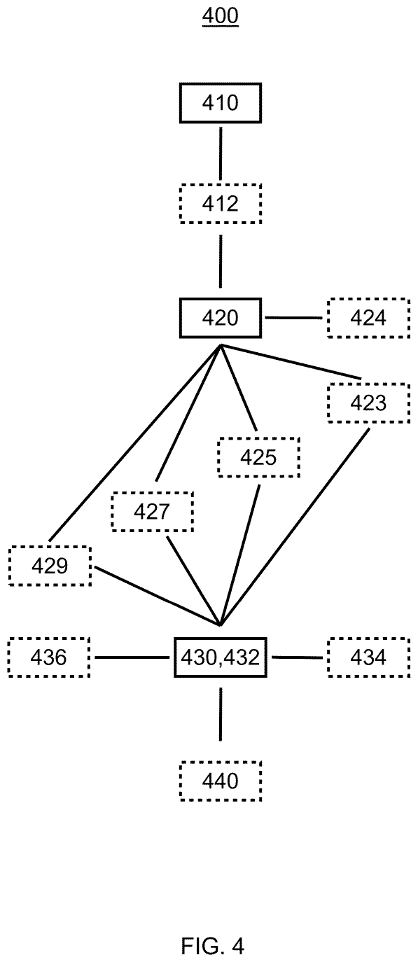

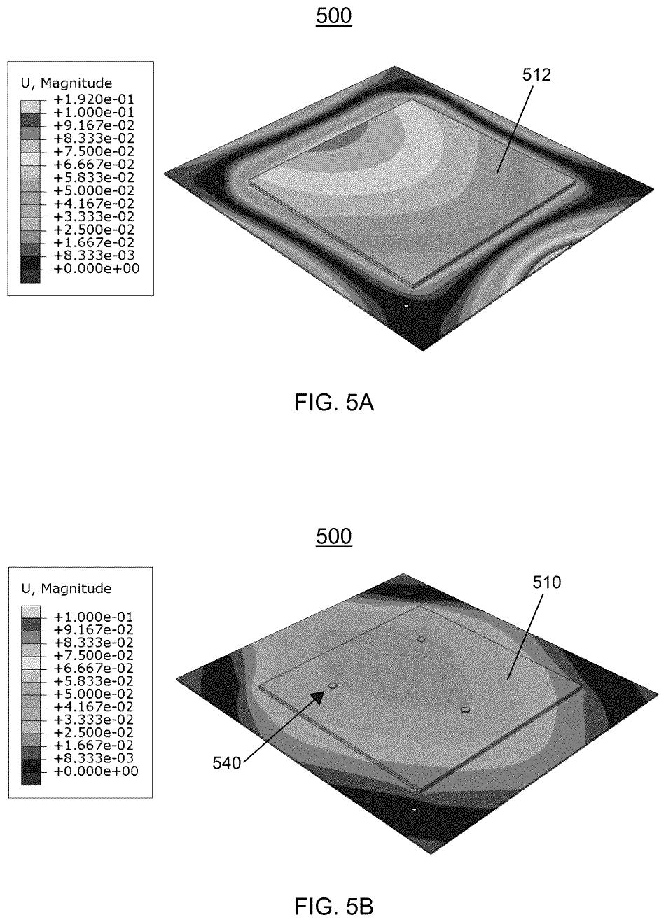

More details and aspects are mentioned in connection with the embodiments described above or below. The examples shown in FIGS. 1A, 1B, 2, and/or 3 may comprise one or more optional additional features corresponding to one or more aspects mentioned in connection with the proposed concept or one or more examples described below (e.g. FIG. 4-5B).

FIG. 4 shows a flowchart of a method 400 for assembling an electronic device. The method includes affixing a shielding structure to a circuit board 410 to at least partially, laterally surround an electrical component on the circuit board. The shielding structure may be rigidly affixed to the circuit board. This may provide extra strength to the lid and system. The method further includes attaching a spring to a fastener 420. The method also includes affixing a lid to the shielding structure 430 and the circuit board 432 so that the lid is affixed to the circuit board with the fastener. Affixing a lid to the shielding structure and the circuit board 430, 432 may provide enhanced structural stiffening for both the board and components attached to the board under the lid. The lid may be rigidly affixed to the shielding structure. This may provide extra strength to system by better distributing forces acting on the lid to the shielding structure. Compared to methods without a lid affixed to a shielding structure and the circuit board, this method 400 may enable the use of thinner circuit boards and smaller or no backing plate. Additionally, compared to other methods, this method 400 may maintain or decrease the height of the system Z-stack (e.g. by supporting the use of thinner components or removing some components like the backing plate). It also may maintain or decrease the weight of the system weight (e.g. by supporting the use of lighter components or removing some components like the backing plate).

The method 400 may further include affixing the fastener to the circuit board 436 through a connection to a stud of a first side of the circuit board and/or a backing plate adjacent to a second side of the circuit board. This may be optionally done when affixing the lid to the circuit board 432. Affixing a fastener to a stud or backing plate may increase the structural stability and integrity of the electronic package, ensuring the secure and reliable attachment of components. This enhanced fastening mechanism may minimize the risk of loosening or detachment, providing a robust and durable assembly that can withstand various mechanical stresses and vibrations. Additionally, affixing a fastener to a stud or backing plate offers ease of assembly during manufacturing and may improve maintenance and repair processes. Other methods without a lid affixed to a shielding structure and the circuit board, may have an increased failure risk at stiff backing plate edge due narrow stiffness transition area. Compared to those methods, this method may reduce the pressure on any transition area of a backing plate and thus may reduce the failure risk. Since lid is attached to the shielding structure (e.g. fence), the lid transfers a part of the load to the structure closer to the fasteners (e.g. mounting screws) and thereby will decrease the board deflection.

The method 400 may further include arranging a cooling structure 424 between the lid and the circuit board and affixing the cooling structure to the circuit board 434 with the fastener. Arranging the cooling structure 424 may be optionally done when attaching a spring to a fastener 420 if the spring is also attached to the cooling structure (e.g. with a leaf spring under then lid). Or it may optionally be done prior to affixing the lid to the shielding structure 430 and circuit board 420. Arranging the cooling structure 424 in the electronic device may improve the thermal management capabilities of the electronic package.

The method the method may further include arranging a spring to apply a load force to drive the cooling structure towards the top of the electrical component 423. This improves the contact and interface between the cooling structure and the components it is intended to cool. The applied load force helps to establish and maintain a consistent and reliable thermal interface, minimizing air gaps and thermal resistance. As a result, the cooling structure can effectively remove heat from the components, optimizing their performance and preventing overheating-related issues.

The method 400 may further include arranging a spring between the lid and the head of the fastener 425. This may distribute the load evenly, ensuring uniform pressure and contact between the lid and the fastener. It may also help absorb vibrations and shocks as well as provide flexibility for expansion, such as those due to thermal variations.

The method 400 may further include arranging a spring between the lid and the circuit board 427. This may target a load to individual components of the circuit board. The spring may also better absorb shocks and vibrations, reducing the risk of mechanical stress and damage to the circuit board.

The method 400 may further include forming an aperture in the lid 412, wherein the fastener extends through the aperture. This may be optionally done at any step of the process prior to affixing the lid to the circuit board 432 with the fastener. Forming an aperture in the lid 412 may allow for easier assembly of the electronic package and ensure precise positioning and alignment of the fasteners. It also offers versatility in accommodating different sizes and types of screws, providing options for customization and adaptability in the assembly process.

The method 400 may further include affixing the lid to the shielding structure 430 via a snap connection. A snap connection may provide a secure and reliable closure as well as provide extra strength over other possible connection options, such as thermal paste.

The method 400 may further include grounding the shielding structure and the lid 440. This creates a conductive path that allows for the dissipation of EMI and static charges. By grounding both the shielding structure and the lid, any stray EMI or electrical charges may be effectively redirected to the ground, minimizing the risk of interference and electrical damage to the internal components. Additionally, grounding improves the overall electromagnetic compatibility (EMC) of the electronic device, ensuring compliance with regulatory standards and reducing the likelihood of performance issues or malfunctions caused by EMI. Lastly, grounding enhances safety by providing a controlled path for electrical currents, reducing the risk of electrical shocks or hazards to users and nearby components.

The method 400 may further include attaching a spacer to the fastener 429 so that the spacer is arranged between the lid and the circuit board. This may allow for a controlled and consistent gap or distance between the lid and the circuit board. This gap may prevent direct contact and potential damage to the circuit board from the pressure exerted by the fastener. The spacer may act as a buffer, absorbing shocks and vibrations, thereby reducing the risk of mechanical stress or impact-related issues. Additionally, the spacer can assist in thermal management by creating a small air gap or allowing for the integration of additional thermal interface materials, improving heat dissipation and temperature regulation within the electronic package.

More details and aspects are mentioned in connection with the embodiments described above or below. The example shown in FIG. 4 may comprise one or more optional additional features corresponding to one or more aspects mentioned in connection with the proposed concept or one or more examples described above or below.

FIGS. 5A and 5B show simulations of load on a circuit board (PCB) 500 without 512 and with a stiffening lid 510. Although the difference between the embodiments may seem, it may have a significant effect on the system stiffness. In FIG. 5A, the fasteners or screws secure electrical components to the PCB under the EMI shield, and in FIG. 5B, the fasteners 540 or screws secure the components to the PCB through the EMI shield. In simulation results at ½ lbf loading, the shield connection was shown to increase stiffness by 50% (at the die area). Three-point bending was made both CPU and GPU dies and an improvement in the bending may be seen below in Table 1.

TABLE 1
Three point bending results with 3 kgf (6.6 lbf) load.

| | CPU | | | GPU | | |
|---|---|---|---|---|---|---|
| | Deflection | Stiffness | | Deflection | Stiffness | |
| | [mm] | [N/mm] | Improvement | [mm] | [N/mm] | Improvement |
| PCB alone | 0.13 | 231 | N/A | 0.11 | 273 | N/A |
| With | 0.070 | 429 | 86% | 0.050 | 600 | 120% |
| stiffener | | | | | | |

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor, or other programmable hardware component. Thus, steps, operations, or processes of different ones of the methods described above may also be executed by programmed computers, processors, or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, and/or optically readable digital data storage media, for example. Other examples may also include computers, processors, control units, (field) programmable logic arrays ((F) PLAs), (field) programmable gate arrays ((F) PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations, or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process, or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

An example (e.g. example 1) electronic device comprising a shielding structure at least partially, laterally surrounding an electrical component on a circuit board. The device further comprising a lid affixed to a top of the shielding structure and covering the electrical component, a spring directly or indirectly applying a load force to the electrical component, and a fastener affixing the lid and the spring to the circuit board.

Another example (e.g. example 2) relates to a previously described example (e.g. example 1), further comprising a cooling structure, wherein the cooling structure is arranged between the lid and the circuit board.

Another example (e.g. example 3) relates to a previously described example (e.g. example 2), wherein the load force drives the cooling structure towards a top of the electrical component.

Another example (e.g. example 4) relates to a previously described example (e.g. one of the examples 2-3), wherein the cooling structure extends from the top of the electrical component through an opening in the shielding structure or between the shielding structure and the lid.

Another example (e.g. example 5) relates to a previously described example (e.g. one of the examples 2-4), wherein the cooling structure extends to a fan.

Another example (e.g. example 6) relates to a previously described example (e.g. one of the examples 2-5), wherein the cooling structure is at least one of a thermal interface material, a vapor chamber, a heat pipe, a liquid cooling system, a phase-change cooling system, and/or a cold plate.

Another example (e.g. example 7) relates to a previously described example (e.g. one of the examples 2-6), wherein the spring applies the load force to the lid and drives the cooling structure towards the top of the electrical component through the lid.

Another example (e.g. example 8) relates to a previously described example (e.g. one of the examples 1-7), wherein the spring is arranged between the lid and a head of the fastener.

Another example (e.g. example 9) relates to a previously described example (e.g. one of the examples 1-7), wherein the spring is arranged between the lid and the circuit board.

Another example (e.g. example 10) relates to a previously described example (e.g. example 9), wherein the spring extends from the fastener to the top of the electrical component.

Another example (e.g. example 11) relates to a previously described example (e.g. one of the examples 1-10), wherein the lid comprises an aperture, wherein the fastener extends through the aperture.

Another example (e.g. example 12) relates to a previously described example (e.g. example 11), wherein the aperture is arranged in a recess of the lid.

Another example (e.g. example 13) relates to a previously described example (e.g. example 12), wherein the recess of the lid has a depth equal to or greater than the height of a head of the fastener.

Another example (e.g. example 14) relates to a previously described example (e.g. example 11), wherein the aperture is arranged in a protrusion.

Another example (e.g. example 15) relates to a previously described example (e.g. one of the examples 11-14), further comprising a seal between the fastener and the aperture.

Another example (e.g. example 16) relates to a previously described example (e.g. example 15), wherein the seal comprises at least one of an EMI gasket, and/or a conductive coating.

Another example (e.g. example 17) relates to a previously described example (e.g. one of the examples 1-16), wherein the lid is affixed to the shielding structure via a snap connection.

Another example (e.g. example 18) relates to a previously described example (e.g. one of the examples 1-17), wherein the fastener is at least one of a screw, a bolt, and/or a rivet.

Another example (e.g. example 19) relates to a previously described example (e.g. one of the examples 1-18), wherein the spring is a leaf spring.

Another example (e.g. example 20) relates to a previously described example (e.g. example 19), wherein a second fastener affixes the leaf spring to the circuit board.

Another example (e.g. example 21) relates to a previously described example (e.g. one of the examples 1-20), wherein the shielding structure and the lid are grounded.

Another example (e.g. example 22) relates to a previously described example (e.g. one of the examples 1-21), wherein the circuit board comprises a stud and wherein the fastener is affixed to the stud of the circuit board.

Another example (e.g. example 23) relates to a previously described example (e.g. one of the examples 1-22), further comprising a spacer, wherein the spacer is arranged between the lid and the circuit board and wherein the fastener extends through a spacer.

Another example (e.g. example 24) relates to a previously described example (e.g. one of the examples 1-23), further comprising a back plate, wherein the circuit board is arranged between the lid and the back plate, wherein the lid is affixed to the circuit board and the back plate by the fastener.

Another example (e.g. example 25) relates to a previously described example (e.g. one of the examples 1-24), wherein the electrical component is at least one of a processor, a memory device, an integrated circuit, a transistor, and/or a power supply unit.

Another example (e.g. example 26) relates to a previously described example (e.g. one of the examples 1-25), wherein the lid is an electromagnetic interference lid.

Another example (e.g. example 27) relates to a previously described example (e.g. one of the examples 1-26), wherein the shielding structure is an electromagnetic interference fence.

An example (e.g. example 1) is a method for assembling an electronic device comprising affixing a shielding structure to a circuit board to at least partially, laterally surround an electrical component on the circuit board. The method further comprises attaching a spring to a fastener and affixing a lid to the shielding structure and the circuit board, wherein the lid is affixed to the circuit board with the fastener.

Another example (e.g. example 29) relates to a previously described example (e.g. example 28), wherein the fastener is affixed to the circuit board through a connection to at least one of a stud of a first side of the circuit board, and/or a back plate adjacent to a second side of the circuit board.

Another example (e.g. example 30) relates to a previously described example (e.g. one of the examples 28-29), further comprising arranging a cooling structure between the lid and the circuit board and affixing the cooling structure to the circuit board with the fastener.

Another example (e.g. example 31) relates to a previously described example (e.g. one of the examples 28-30), wherein the spring is arranged to apply a load force to drive the cooling structure towards a top of the electrical component.

Another example (e.g. example 32) relates to a previously described example (e.g. one of the examples 28-31), wherein the spring is arranged between the lid and a head of the fastener.

Another example (e.g. example 33) relates to a previously described example (e.g. one of the examples 28-31), wherein the spring is arranged between the lid and the circuit board.

Another example (e.g. example 34) relates to a previously described example (e.g. one of the examples 28-33), further comprising forming an aperture in the lid, wherein the fastener extends through the aperture.

Another example (e.g. example 35) relates to a previously described example (e.g. one of the examples 28-34), further comprising affixing the lid to the shielding structure via a snap connection.

Another example (e.g. example 36) relates to a previously described example (e.g. one of the examples 28-35), further comprising grounding the shielding structure and the lid.

Another example (e.g. example 37) relates to a previously described example (e.g. one of the examples 28-36), further comprising attaching a spacer to the fastener, wherein the spacer is arranged between the lid and the circuit board.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. An electronic device comprising:
a shielding structure at least partially, laterally surrounding an electrical component on a circuit board,
a lid affixed to a top of the shielding structure and covering the electrical component,
a spring directly or indirectly applying a load force to the electrical component,
a cooling structure, wherein the cooling structure is arranged between the lid and the circuit board, and
a fastener affixing the lid and the spring to the circuit board.

2. The electronic device of claim 1, wherein the load force drives the cooling structure towards a top of the electrical component.

3. The electronic device of claim 2, wherein the cooling structure extends from the top of the electrical component through an opening in the shielding structure or between the shielding structure and the lid.

4. The electronic device of claim 3, wherein the cooling structure extends to a fan.

5. The electronic device of claim 1, wherein the cooling structure is at least one of:
a thermal interface material,
a vapor chamber,
a heat pipe,
a liquid cooling system,
a phase-change cooling system, and/or
a cold plate.

6. The electronic device of claim 1, wherein the spring applies the load force to the lid and drives the cooling structure towards the top of the electrical component through the lid.

7. The electronic device of claim 1, wherein the spring is arranged between the lid and a head of the fastener.

8. The electronic device of claim 1, wherein the spring is arranged between the lid and the circuit board.

9. The electronic device of claim 1, wherein the lid comprises an aperture, wherein the fastener extends through the aperture.

10. The electronic device of claim 9, wherein the aperture is arranged in a recess of the lid.

11. The electronic device of claim 10, wherein the recess of the lid has a depth equal to or greater than the height of a head of the fastener.

12. The electronic device of claim 1, wherein the lid is affixed to the shielding structure via a snap connection.

13. The electronic device of claim 1, wherein the fastener is at least one of:
a screw,
a bolt, and/or
a rivet.

14. The electronic device of claim 1, wherein the spring is a leaf spring.

15. The electronic device of claim 14, wherein a second fastener affixes the leaf spring to the circuit board.

16. The electronic device of claim 1, wherein the circuit board comprises a stud and wherein the fastener is affixed to the stud of the circuit board.

17. The electronic device of claim 1, further comprising a back plate, wherein the circuit board is arranged between the lid and the back plate, wherein the lid is affixed to the circuit board and the back plate by the fastener.

18. The electronic device of claim 1, wherein the lid is an electromagnetic interference lid.

19. The electronic device of claim 1, wherein the shielding structure is an electromagnetic interference fence.

20. A method for assembling an electronic device, the method comprising:
affixing a shielding structure to a circuit board to at least partially, laterally surround an electrical component on the circuit board,
attaching a spring to a fastener,
arranging a cooling structure between a lid and the circuit board,
affixing the lid to the shielding structure, and
affixing the lid and the cooling structure to the circuit board, wherein the lid and the cooling structure are affixed to the circuit board with the fastener.
